(19) United States
(12) Patent Application Publication
(10) Pub. No.: US 2026/0328869 A1
(43) Pub. Date: Oct. 22, 2026

(54) CONNECTION DETECTION CIRCUIT

(71) Applicant: ITE Tech. Inc., Hsinchu (TW)

(72) Inventors: Tsung-Han Wu, Hsinchu City (TW); Dong-Shan Chen, Hsinchu County (TW)

(73) Assignee: ITE Tech. Inc., Hsinchu (TW)

(21) Appl. No.: 19/276,026

(22) Filed: Jul. 22, 2025

(30) Foreign Application Priority Data
Apr. 18, 2025 (TW) 114114689

(51) Int. Cl. G01R 31/68; H02M 1/00

(52) U.S. Cl. CPC G01R 31/68; G06F 1/32; G06F 1/3206; H02M 1/0032

(57) ABSTRACT

A connection detection circuit including a pre-detection circuit and a connection circuit is implemented in a first electronic device. When the first electronic device operates in a power-saving mode, the connection detection circuit turns off the connection circuit with higher power consumption, and turns on the pre-detection circuit with lower power consumption for determining whether a second electronic device is inserted into the first electronic device. When the first electronic device operates in a normal mode or when the pre-detection circuit determines that the second electronic device is inserted into the first electronic device during the power-saving mode, the connection detection circuit turns off the pre-detection circuit with lower detection accuracy, and turns on the connection circuit with higher detection accuracy for accurately determining the connection status of the first electronic device and the second electronic device.

### BACKGROUND OF THE INVENTION

### 1. Field of the Invention

The present invention is related to a connection detection circuit, and more particularly, to a connection detection circuit capable of maintaining low-power connection detection function in a power-saving mode.

### 2. Description of the Prior Art

Electronic devices are often equipped with various types of interfaces, which enable power and/or data delivery between devices. One example of such interface is the Universal Serial Bus (USB) interface. USB is an industry standard developed by the USB Implementers Forum (USB IF), which defines characteristics of the cables, connectors and communications protocols used in a bus for connection, communication, and power delivery between computers and electronic devices. USB has become the most popular interface due to advantages such as plug-and-play, convenient operation, low cost, versatility and easy development. USB Type-C specification can support data, audio, video transmission, reversible plugging, and high-efficiency charging, high compatibility and high transmission rate, and is thus widely used in information and communication technology (ICT) devices such as monitors, desktops, tablets, and mobile phones.

Related USB Type-C standards define voltage-dividing behaviors for different connection status, and electronic devices compatible with the USB Type-C interface are usually equipped with a set of special connection detection circuits for detecting the connection status of external devices. A prior art connection detection circuit typically includes pull-up circuits, pull-down circuits, comparators, and analog digital converters (ADCs). In the prior art, after an electronic device enters the power-saving mode, its connection detection circuit still maintains operation and thus keeps consuming power. If the electronic device turns off its connection detection circuit after entering the power-saving mode, it is unable to maintain connection detection function in the power-saving mode.

### SUMMARY OF THE INVENTION

The present invention provides a connection detection circuit implemented in a first electronic device for maintaining low-power connection detection function in a power-saving mode. The connection detection circuit includes a first pre-detection circuit and a first connection circuit. The first pre-detection circuit is configured to turn on after the first electronic device switches from a normal mode to the power-saving mode for determining whether a second electronic device is inserted into the first electronic device. The first connection circuit is configured to turn on when the first electronic device operates in the normal mode; turn off after the first electronic device switches from the normal mode to the power-saving mode; and turn on after the first pre-detection circuit determines that the second electronic device is inserted into the first electronic device when the first electronic device operates in the power-saving mode for determining a connection status of the first electronic device and the second electronic device. The first electronic device consumes more power when operating in the normal mode than when operating in the power-saving mode. The first connection circuit in operation consumes more power than the first pre-detection circuit in operation. Accuracy of the first connection circuit in detecting connection status is better than accuracy of the first pre-detection circuit in detecting connection status.

Therefore, there is a need for a connection detection circuit capable of maintaining low-power connection detection function in a power-saving mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a functional diagrams illustrating a connection detection circuit capable of maintaining low-power connection detection function in a power-saving mode according to an embodiment of the present invention.

FIG. 1B is a functional diagrams illustrating a connection detection circuit capable of maintaining low-power connection detection function in a power-saving mode according to another embodiment of the present invention.

FIG. 2A is a diagram illustrating the pin layout of a USB Type-C socket.

FIG. 2B is a diagram illustrating the pin layout of a USB Type-C plug.

FIG. 3 is a diagram illustrating an implementation of a connection circuit in the connection detection circuit according to an embodiment of the present invention.

FIG. 4 is a diagram illustrating an implementation of a pre-connection circuit in the connection detection circuit according to an embodiment of the present invention.

FIG. 5 is a flowchart illustrating the operation of the connection detection circuit according to an embodiment of the present invention.

FIGS. 6A-6D are diagrams illustrating various circuit configurations of the connection detection circuit depicted in FIG. 1A during operation according to embodiments of the present invention.

FIGS. 7A-7D are diagrams illustrating various circuit configurations of the connection detection circuit depicted in FIG. 1A during operation according to embodiments of the present invention.

FIGS. 8A-8C are diagrams illustrating various circuit configurations of the connection detection circuit depicted in FIG. 1B during operation according to embodiments of the present invention.

FIGS. 9A-9C are diagrams illustrating various circuit configurations of the connection detection circuit depicted in FIG. 1B during operation according to embodiments of the present invention.

FIG. 10 is a signal diagram illustrating the operation of a pre-detection circuit in the DRP mode according to an embodiment of the present invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

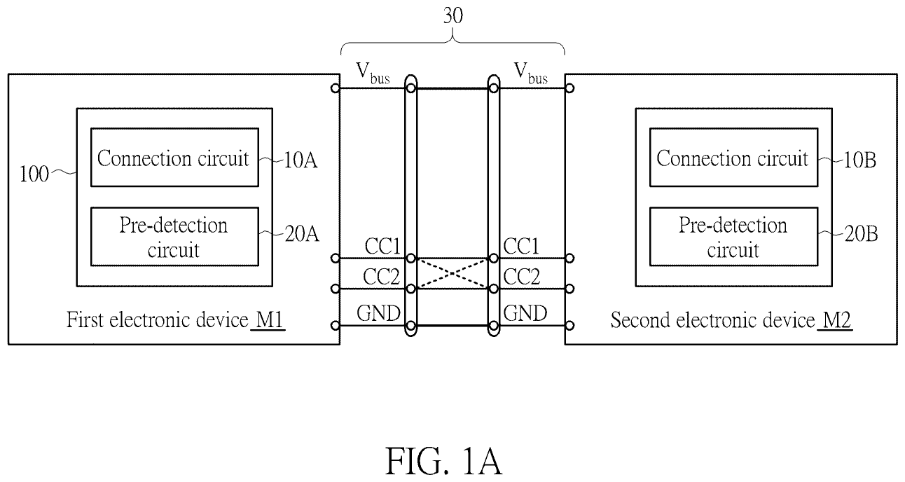

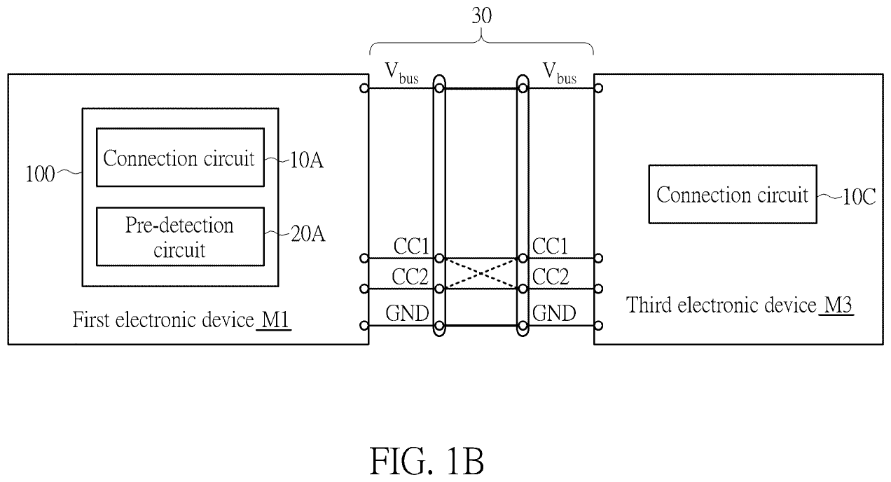

FIGS. 1A and 1B are functional diagrams illustrating a connection detection circuit 100 capable of maintaining low-power connection detection function in a power-saving mode according to embodiments of the present invention. The connection detection circuit 100 includes a connection circuit 10A and a pre-detection circuit 20A and may be implemented in a first electronic device M1. The first electronic device M1 may be coupled to an external device (such as a second electronic device M2 or a third electronic device M3) via a connection interface 30, and the connection detection circuit 100 is configured to determine whether the second electronic device M2 or the third electronic device M3 is inserted into the first electronic device M1. In the embodiment depicted in FIG. 1A, the second electronic device M2 includes a connection circuit 10B and a pre-detection circuit 20B. In the embodiment depicted in FIG. 1B, the third electronic device M3 includes a connection circuit 10C.

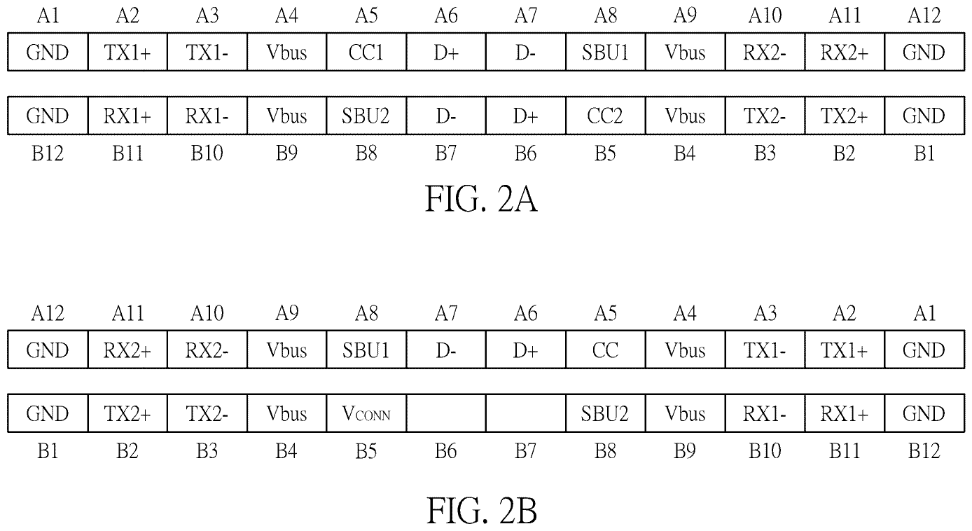

In an embodiment of the present invention, the connection interface 30 may adopt USB Type-C standard. FIG. 2A is a diagram illustrating the pin layout of a USB Type-C socket, and FIG. 2B is a diagram illustrating the pin layout of a USB Type-C plug. In order to support forward/reverse insertion, each of the USB Type-C plug and the USB Type-C socket includes a set of pins with symmetrical orientation and designated by A1-A12 and B1-B12. The differential data bus pins TX1+/TX1−/RX1+/RX1− and TX2+/TX2/RX2+/RX2− pins are used for transmitting data signals. The power supply pin Vbus is used for transmitting power signals, and the power supply pin Vconn (only on USB Type-C socket) is used for powering Type-C cable controller. The configuration channel pins CC1/CC2 are used to detect the orientation of insertion, the connection status, determine downstream facing port (DFP) and upstream facing port (UFP), configure the power supply pins Vbus and Vconn, configure alternate or accessory mode, and execute procedures related to power delivery (PD) communications. The data pins D+ and D− are compatible with USB 2.0 standard. The sideband use pins SBU1/SBU2 are used for transmitting control signals, and the ground pin GND is coupled to a ground level. When it is determined that a connection has been established based on the configuration channel pins CC1/CC2, power may be supplied via the power supply pin Vbus of a PD source device.

For example, the connection interface 30 may be a USB Type-C cable with both ends each accommodating a USB Type-C plug depicted in FIG. 2B. Meanwhile, the USB Type-C socket depicted in FIG. 2A is disposed on each of the first electronic device M1, the second electronic device M2 and the third electronic device M3. When the USB Type-C socket of the first electronic device M1 is connected to the USB Type-C plug on the first end of the USB Type-C cable and the USB Type-C plug on the second end of the USB Type-C cable is connected to the USB Type-C socket of the second electronic device M2 or the third electronic device M3, data communication and power delivery may be conducted between two electronically-connected electronic devices. For ease of explanation, FIGS. 1A and 1B only depict the power supply pin Vbus, the configuration channel pins CC1/CC2 and the ground pin of the first electronic device M1, the second electronic device M2, the third electronic device M3 and the connection interface 30. Also, the implementation of the connection interface 30 does not limit the scope of the present invention.

In the present invention, the connection circuit 10A in the connection detection circuit 100 is able to detect the load impedance of the configuration channel pins CC1/CC2 in the first electronic device M1, thereby determining the connection status with an external device (such as the second electronic device M2 or the third electronic device M3). Since each connection status has its own unique voltage-dividing behavior, the connection circuit 10A requires more complicated circuitry in order to differentiate between different voltage-dividing behaviors. Therefore, the connection circuit 10A can provide highly accurate connection status detection, but consumes more power when in operation.

In the present invention, the pre-detection circuit 20A in the connection detection circuit 100 is able to detect the voltages of the configuration channel pins CC1/CC2 in the first electronic device M1, thereby determining whether an external device (such as the second electronic device M2 or the third electronic device M3) is inserted. Since the pre-detection circuit 20A is only required to detect the voltage variation on a single pin, it consumes less power when in operation but is unable to provide highly accurate connection status detection.

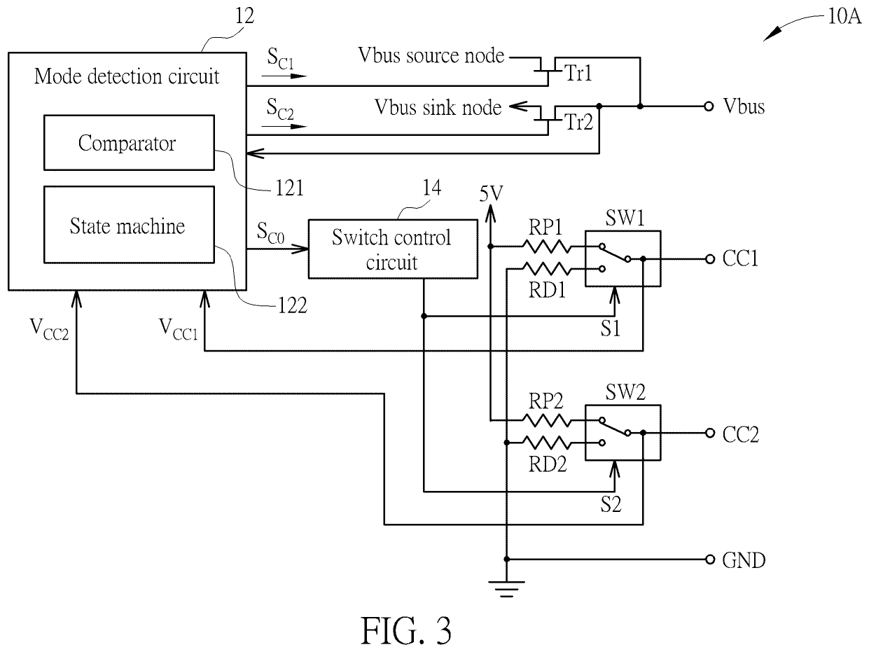

FIG. 3 is a diagram illustrating an implementation of the connection circuit 10A in the connection detection circuit 100 according to an embodiment of the present invention. The connection circuit 10A includes switching circuits SW1 and SW2, pull-up resistors RP1 and RP2, pull-down resistors RD1 and RD2, a mode detection circuit 12, a switch control circuit 14 and transistors Tr1 and Tr2.

The first end of the pull-up resistor RP1 may be selectively coupled to the configuration channel pin CC1 of the first electronic device M1 via the switching circuit SW1, and the second end of the pull-up resistor RP1 may be coupled to a power supply voltage level (such as 5V). The first end of the pull-down resistor RD1 may be selectively coupled to the configuration channel pin CC1 of the first electronic device M1 via the switching circuit SW1, and the second end of the pull-down resistor RD1 may be coupled to the ground pin GND of the first electronic device M1. The first end of the pull-up resistor RP2 may be selectively coupled to the configuration channel pin CC2 of the first electronic device M1 via the switching circuit SW2, and the second end of the pull-up resistor RP2 may be coupled to a power supply voltage level (such as 5V). The first end of the pull-down resistor RD2 may be selectively coupled to the configuration channel pin CC2 of the first electronic device M1 via the switching circuit SW2, and the second end of the pull-down resistor RD2 is coupled to ground pin GND of the first electronic device M1. Meanwhile, a voltage V_{CC1} associated with the configuration channel pin CC1 and a voltage V_{CC2} associated with the configuration channel pin CC2 are supplied to the mode detection circuit 12. This way, the connection circuit 10A may obtain the load impedance of the configuration channel pins CC1/CC2 in the first electronic device M1, thereby determining the connection status with an external device (such as the second electronic device M2).

The mode detection circuit 12 includes a comparator 121 and a state machine 122. The comparator 121 may determine the load impedance of the configuration channel pins CC1/CC2 based on the voltage V_{CC1} associated with the configuration channel pin CC1 and the voltage V_{CC2} associated with the configuration channel pin CC2, and the state machine 122 may determine the connection status with an external device (such as the second electronic device M2 or the third electronic device M3) based on the determination result the comparator 121. On the other hand, the mode detection circuit 12 may generate control signals S_{C0}-S_{C2} for controlling the operation of the switch control circuit 14, the transistor Tr1 and the transistor Tr2, respectively.

The switch control circuit 14 is configured to generate control signals S1 and S2 based on the control signal S_{CO} generated by the mode detection circuit 12 for controlling the operation of the switching circuits SW1 and SW2, respectively. More specifically, if the first electronic device M1 functions as a PD source device, the switching circuits SW1 and SW2 are set to a first state (as depicted in FIG. 3) respectively by the control signals S1 and S2 generated by the switch control circuit 14, i.e., the configuration channel pins CC1 and CC2 are coupled to the first ends of the pull-up resistors RP1 and RP2, respectively. If the first electronic device M1 functions as a PD sink device, the switching circuits SW1 and SW2 are set to a second state (not shown in FIG. 3) respectively by the control signals S1 and S2 generated by the switch control circuit 14, i.e., the configuration channel pins CC1 and CC2 are coupled to the first ends of the pull-down resistors RD1 and RD2, respectively. In an embodiment, each of the switching circuits SW1 and SW2 may be a single pole double throw (SPDT) switch. However, the type of the switching circuits SW1 and SW2 does not limit the scope of the present invention.

When it is determined that an external device is inserted into the first electronic device M1 functioning as a PD source device, the transistor Tr1 is turned on by the control signal S_{C1} generated by the mode detection circuit 12 and the transistor Tr2 is cut off by the control signal S_{C2} generated by the mode detection circuit 12, thereby coupling the power supply pin Vbus to a VBUS source node for supplying power to the external device (such as to the second electronic device M2 or the third electronic device M3). When it is determined that an external device is inserted into the first electronic device M1 functioning as a PD sink device, the transistor Tr1 is cut off by the control signal S_{C1} generated by the mode detection circuit 12 and the transistor Tr2 is turned on by the control signal S_{C2} generated by the mode detection circuit 12, thereby coupling the power supply pin Vbus to a VBUS sink node for receiving power from the external device (such as from the second electronic device M2 or the third electronic device M3).

In an embodiment of the present invention, the connection circuit 10B of the second electronic device M2 and the connection circuit 10C of the third electronic device may adopt the same structure as the connection circuit 10A of the first electronic device M1, but is not limited thereto. In the present invention, the first electronic device M1, the second electronic device M2 and the third electronic device may adopt different types or the same type of connection circuit.

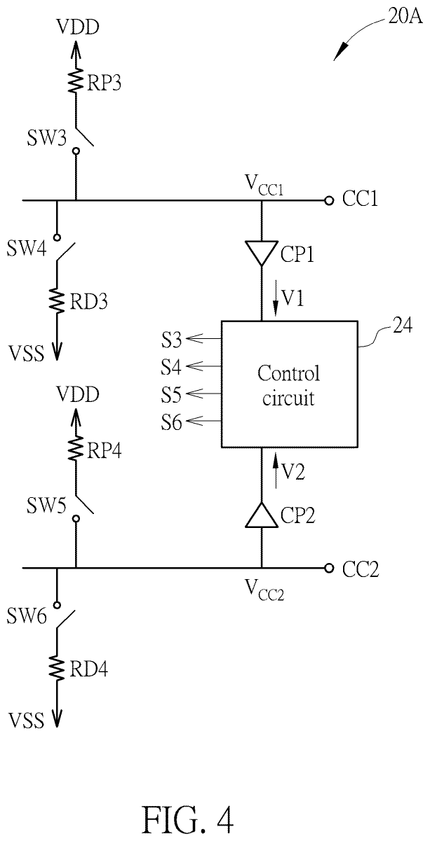

FIG. 4 is a diagram illustrating an implementation of the pre-connection circuit 20A in the connection detection circuit 100 according to an embodiment of the present invention. The pre-detection circuit 20A includes switching circuits SW3 and SW4, pull-up resistors RP3 and RP4, pull-down resistors RD3 and RD4, and a control circuit 24. The first end of the pull-up resistor RP3 is coupled to a bias voltage VDD, and the second end of the pull-up resistor RP3 may be selectively coupled to the configuration channel pin CC1 of the first electronic device M1 via the switching circuit SW3. The first end of the pull-down resistor RD3 may be selectively coupled to the configuration channel pin CC1 of the first electronic device M1 via the switching circuit SW4, and the second end of the pull-down resistor RD3 is coupled to a bias voltage VSS, wherein the level of the bias voltage VDD is higher than the level of the bias voltage VSS (for example, VDD is a positive voltage, and VSS is a negative voltage or a ground voltage). The first end of the pull-up resistor RP4 is coupled to the bias voltage VDD, and the second end of the pull-up resistor RP4 may be selectively coupled to the configuration channel pin CC2 of the first electronic device M1 via the switching circuit SW5. The first end of the pull-down resistor RD4 may be selectively coupled to the configuration channel pin CC2 of the first electronic device M1 via the switching circuit SW6, and the second end of the pull-down resistor RD4 is coupled to the bias voltage VSS. The input end of the comparator CP1 is coupled to the configuration channel pin CC1 of the first electronic device M1, and the output end of the comparator CP1 is coupled to the control circuit 24. The input end of the comparator CP2 is coupled to the configuration channel pin CC2 of the first electronic device M1, and the output end of the comparator CP2 is coupled to the control circuit 24. The control circuit 24 is configured to generate control signals S3-S6 for controlling the operation of the switching circuits SW3-SW6, respectively.

In an embodiment of the present invention, each of the comparators CP1 and CP2 may be implemented by a comparing circuit with positive feedback, such as a Schmitt trigger. When the voltage established on the input end of the comparator CP1 is higher than its input high voltage ViH1, the comparator CP1 is configured to output a logic-1 voltage; when the voltage established on the input end of the comparator CP1 is lower than its input low voltage ViL1, the comparator CP1 is configured to output a logic-0 voltage. Similarly, when the voltage established on the input end of the comparator CP2 is higher than its input high voltage ViH2, the comparator CP2 is configured to output a logic-1 voltage; when the voltage established on the input end of the comparator CP2 is lower than its input low voltage ViL2, the comparator CP1 is configured to output a logic-0 voltage. However, the implementation of the comparators CP1 and CP2 does not limit the scope of the present invention.

In an embodiment of the present invention, each of the switching circuits SW3-SW6 may be a single pole single throw (SPST) switch, a metal-oxide-semiconductor field-effect transistor (MOSFET), a bipolar junction transistor (BJT), or any device with similar function. The switching circuits SW3-SW6 may be set to an ON state or an OFF state by the control signals S3-S6, respectively. However, the implementation of the switching circuits SW3-SW6 does not limit the scope of the present invention.

In an embodiment of the present invention, the pre-detection circuit 20B of the second electronic device M2 may adopt the same structure as the pre-detection circuit 20A of the first electronic device M1. More specifically, the pre-detection circuit 20B may include switching circuits SW3′ and SW4′, pull-up resistors RP3′ and RP4′, pull-down resistors RD3′ and RD4′, and a control circuit 26 coupled to each other and function in the same way as the pre-detection circuit 20A depicted in FIG. 4. Detailed descriptions of the pre-detection circuit 20B are omitted for clarity.

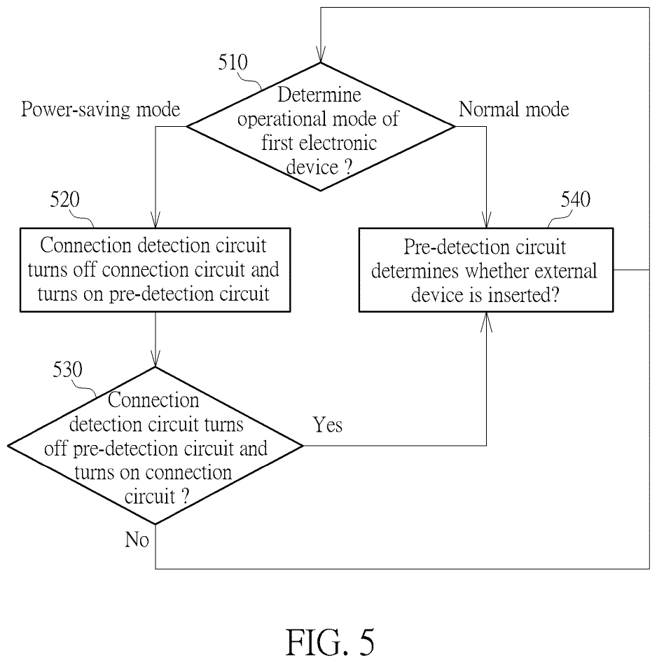

FIG. 5 is a flowchart illustrating the operation of the connection detection circuit 100 according to an embodiment of the present invention. The flowchart in FIG. 5 includes the following steps:

Step 510: determine the operational mode of the first electronic device M1? Execute step 540 when the first electronic device M1 operates in a normal mode; execute step 520 when the first electronic device M1 operates in a power-saving mode.

Step 520: the connection detection circuit 100 turns off the connection circuit 10A and turns on the pre-detection circuit 20A.

Step 530: the pre-detection circuit 20A determines whether an external device is inserted? If yes, execute step 540; if no, execute step 510.

Step 540: the connection detection circuit 100 turns off the pre-detection circuit 20A and turns on the connection circuit 10A; execute step 510.

In step 510, the operational mode of the first electronic device M1 is determined. In the normal mode, all devices of the first electronic device M1 operate with default efficiency, resulting in larger power consumption. In the power-saving mode, all data is stored in the system memory or hard drive before shutting down some or all devices for reducing power consumption. In an embodiment of the present invention, the power-saving mode may be a sleeping mode or a hibernate mode, but is not limited thereto.

When it is determined in step 510 that the first electronic device M1 is operating in the power-saving mode, step 520 is then executed for turning off the connection circuit 10A with larger power consumption and turning on the pre-detection circuit 20A with lower power consumption in the connection detection circuit 100. When it is determined in step 510 that the first electronic device M1 is operating in the normal mode, step 540 is then executed for turning off the pre-detection circuit 20A with lower detection accuracy and turning on the connection circuit 10A with higher detection accuracy in the connection detection circuit 100.

The embodiment depicted in FIG. 4 is used to illustrate the operation of the pre-detection circuit 20A. In an embodiment, the switching circuits SW3 and SW5 are set to the ON state respectively by the control signals S3 and S5 outputted by the control circuit 24, thereby coupling the second ends of the pull-up resistors RP3 and RP4 to the configuration channel pins CC1 and CC2, respectively. Meanwhile, the switching circuits SW4 and SW6 are set to the OFF state respectively by the control signals S4 and S6 outputted by the control circuit 24, thereby isolating the first ends of the pull-down resistors RD3 and RD4 from the configuration channel pins CC1 and CC2, respectively. Under such h circumstance, the configuration channel pins CC1 and CC2 of the first electronic device M1 are coupled to the bias voltage VDD respectively via the pull-up resistors RP3 and RP4, and the pre-detection circuit 20A is configured to detect whether an external device (such as the second electronic device M2 or the third electronic device M3) is inserted into the first electronic device M1 using the pull-up resistors RP3 and RP4. As previously stated, the voltage V_{CC1} associated with the configuration channel pin CC1 and the voltage V_{CC2} associated with the configuration channel pin CC2 may vary due to the insertion of the external device or another reason. When the voltage V_{CC1} drops from VDD to a level which causes the voltage established on the input end of the comparator CP1 to be lower than its input low voltage ViL1, the comparator CP1 is configured to output a logic-0 voltage V1; when the voltage V_{CC2} drops from VDD to a level which causes the voltage established on the input end of the comparator CP2 to be lower than its input low voltage ViL2, the comparator CP2 is configured to output a logic-0 voltage V2. After receiving the logic-0 voltage V1 or V2, the control circuit 24 may determine in step 530 that an external device (such as the second electronic device M2 or the third electronic device M3) is inserted into the first electronic device M1 and then wake up the connection circuit 10A in step 540 for providing connection status detection with high accuracy.

In an embodiment, the switching circuits SW3 and SW5 are set to the OFF state respectively by the control signals S3 and S5 outputted by the control circuit 24, thereby isolating the second ends of the pull-up resistors RP3 and RP4 from the configuration channel pins CC1 and CC2, respectively. Meanwhile, the switching circuits SW4 and SW6 are set to the ON state respectively by the control signals S4 and S6 outputted by the control circuit 24, thereby coupling the first ends of the pull-down resistors RD3 and RD4 to the configuration channel pins CC1 and CC2, respectively. Under such circumstance, the configuration channel pins CC1 and CC2 of the first electronic device M1 are coupled to the bias voltage VSS respectively via the pull-down resistors RD3 and RD4, and the pre-detection circuit 20A is configured to detect whether an external device (such as the second electronic device M2 or the third electronic device M3) is inserted into the first electronic device M1 using the pull-down resistors RD3 and RD4. As previously stated, the voltage V_{CC1} associated with the configuration channel pin CC1 and the voltage V_{CC2} associated with the configuration channel pin CC2 may vary due to the insertion of the external device or another reason. When the voltage V_{CC1} rises from VSS to a level which causes the voltage established on the input end of the comparator CP1 to be higher than its input high voltage ViH1, the comparator CP1 is configured to output a logic-1 voltage V1; when the voltage Voce rises from VSS to a level which causes the voltage established on the input end of the comparator CP2 to be higher than its input high voltage ViH2, the comparator CP2 is configured to output a logic-1 voltage V2. After receiving the logic-1 voltage V1 or V2, the control circuit 24 may determine in step 530 that an external device (such as the second electronic device M2 or the third electronic device M3) is inserted into the first electronic device M1 and then wake up the connection circuit 10A in step 540 for providing connection status detection with high accuracy.

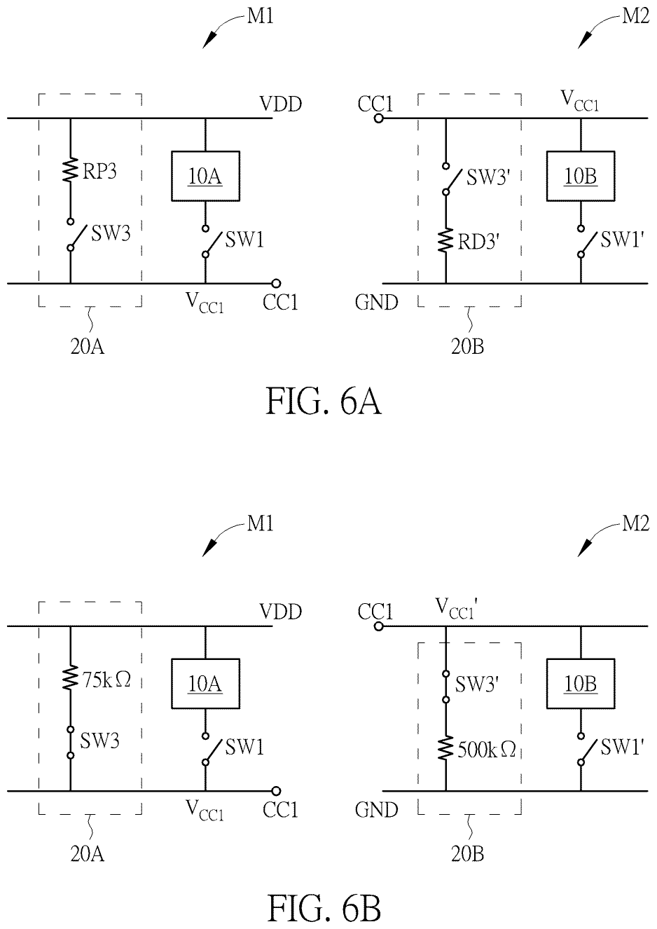

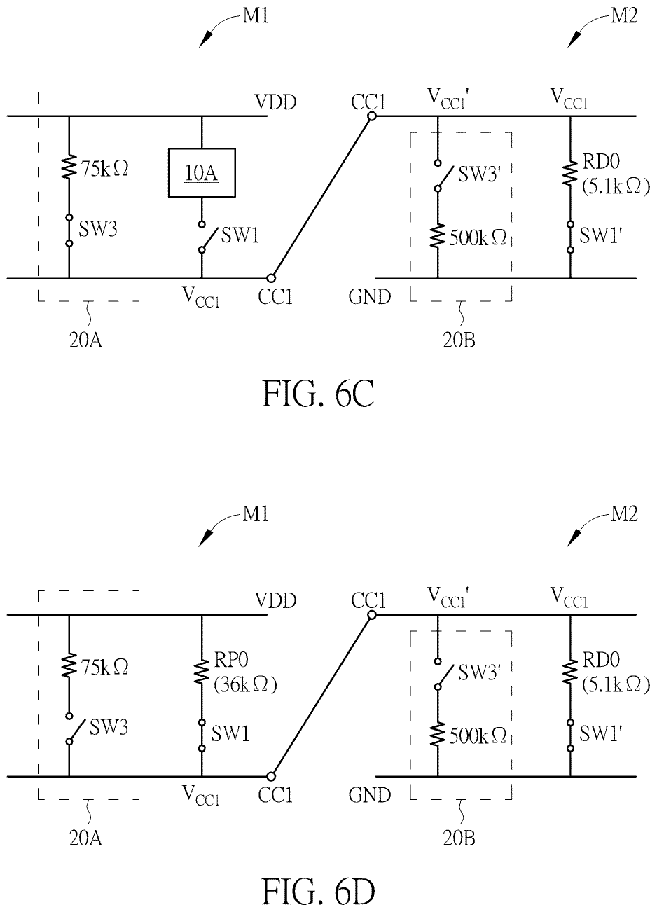

FIGS. 6A-6D are diagrams illustrating various circuit configurations of the connection detection circuit 100 depicted in FIG. 1A during operation according to embodiments of the present invention. For illustrative purpose, it is assumed that the switching circuits SW3 and SW5 are set to the ON state by the control signals S3 and S5 outputted by the control circuit 24 and the switching circuits SW4 and SW6 are set to the OFF state by the control signals S4 and S6 outputted by the control circuit 24. That is, the second ends of the pull-up resistors RP3 and RP4 are respectively coupled to the configuration channel pins CC1 and CC2, and the first ends of the pull-down resistors RD3 and RD4 are respectively isolated from the configuration channel pins CC1 and CC2. Under such circumstances, the configuration channel pins CC1 and CC2 of the first electronic device M1 are coupled to the bias voltage VDD respectively via the pull-up resistors RP3 and RP4, and the pre-detection circuit 20A of the first electronic device M1 is configured to detect whether an external device (such as the second electronic device M2) is inserted into the first electronic device M1 using the pull-up resistors RP3 and RP4. Meanwhile, it is also assumed that the second electronic device M2 is configured to detect whether an external device (such as the first electronic device M1) is inserted using the pull-up resistors RP3′ and RP4′ in the same manner. For ease of explanation, FIGS. 6A-6D only depict the operation of connection detection associated with the configuration channel pin CC1. Detailed descriptions of connection detection associated with the configuration channel pin CC2 are omitted for clarity.

In the embodiment depicted in FIG. 6A, the pull-up resistor RP3 in the pre-detection circuit 20A of the first electronic device M1 is smaller than the pull-down resistor RD3′ in the pre-detection circuit 20B of the second electronic device M2. For example, the value of the pull-up resistor RP3 may be 75 kΩ, and the value of the pull-down resistor RD3′ may be 500 kΩ.

As depicted in FIG. 6B, when the first electronic device M1 and the second electronic device M2 are not connected to each other, the first electronic device M1 and the second electronic device M2 are configured to detect whether an external device is inserted using the pre-detection circuits 20A and 20B, respectively, while the connection circuits 10A and 10B are turned off for reducing power consumption. Under such circumstance, the voltage V_{CC1} associated with the configuration channel pin CC1 of the first electronic device M1 is pulled up to the bias voltage VDD via the pull-up resistor RP3 (e.g., 75 kΩ), and the voltage V_{CC1}′ associated with the configuration channel pin CC1 of the second electronic device M2 is pulled down to the ground level GND via the pull-down resistor RD3′ (e.g., 500 kΩ). In other words, when the first electronic device M1 and the second electronic device M2 are not connected to each other, the configuration channel pin CC1 of the first electronic device M1 is at a high logic level, and the configuration channel pin CC1 of the second electronic device M2 is at a low logic level.

As depicted in FIG. 6C, after the first electronic device M1 and the second electronic device M2 are connected to each other, the configuration channel pin CC1 of the first electronic device M1 and the configuration channel pin CC1 of the second electronic device M2 are at the same level (V_{CC1}=V_{CC1}′). Since the pull-up ability of the pull-up resistor RP3 (e.g., 75 kΩ) is stronger than the pull-down ability of the pull-down resistor RD3′ (e.g., 500 kΩ), the voltage V_{CC1}′ associated with the configuration channel pin CC1 of the second electronic device M2 is pulled up from the ground level GND. When the voltage V_{CC1}′ is greater than the input high voltage ViH1 of the comparator CP1′, the second electronic device M2 determines that the voltage V_{CC1}′ has switched from a low logic level to a high logic level, thereby determining that an external device (such as the first electronic device M1) is inserted into the second electronic device M2. Under such circumstance, the second electronic device M2 is configured to turn off the pre-detection circuit 20B (by setting the switching circuit SW3′ to the OFF state) and turn on the connection circuit 10B (by setting the switching circuit SW1′ to the ON state) for providing connection status detection function with high accuracy. In this case, the equivalent resistor of the connection circuit 10B in the second electronic device M2 is equal to a specification-defined pull-down resistor RD0 (e.g., 5.1 kΩ).

As depicted in FIG. 6D, after the second electronic device M2 turns off the pre-detection circuit 20B and turns on the connection circuit 10B, since the specification-defined pull-down resistor RD0 (e.g., 5.1 kΩ) is smaller than the pull-up resistor RP3 (e.g., 75 kΩ) of the pre-detection circuit 20A in the first electronic device M1, the pull-up ability of the pull-up resistor RP3 (e.g., 75 kΩ) thus becomes weaker than the pull-down ability of the specification-defined pull-down resistor RD0 (e.g., 5.1 kΩ), thereby pulling down the voltage V_{CC1} associated with the configuration channel pin CC1 of the first electronic device M1. When the voltage V_{CC1} is smaller than the input low voltage ViL1 of the comparator CP1, the first electronic device M1 determines that the voltage V_{CC1} has switched from a high logic level to a low logic level, thereby determining that an external device (such as the second electronic device M2) is inserted into the first electronic device M1. Under such circumstance, the first electronic device M1 is configured to turn off the pre-detection circuit 20A (by setting the switching circuit SW3 to the OFF state) and turn on the connection circuit 10A (by setting the switching circuit SW1 to the ON state) for providing connection status detection function with high accuracy. In this case, the equivalent resistor of the connection circuit 10A in the first electronic device M1 is equal to a specification-defined pull-up resistor RP0 (e.g., 36 kΩ).

As depicted in FIGS. 6A-6D, in the case when the first electronic device M1 uses pull-up resistors and the second electronic device M2 uses pull-down resistors for detecting whether an external device is inserted, the present invention may set the pull-up resistor of the pre-detection circuit 20A to be smaller than the pull-down resistor of the pre-detection circuit 20B for providing a condition V_{CC1}′>ViH1′ based on which the second electronic device M2 wakes up the connection circuit 10B, and set the pull-up resistor of the pre-detection circuit 20A in the first electronic device M1 to be greater than the specification-defined pull-down resistor of the second electronic device M2 for providing a condition V_{CC1}′<ViL1 based on which the first electronic device M1 wakes up the connection circuit 10A.

Similarly, in the case when the first electronic device M1 uses pull-down resistors and the second electronic device M2 uses pull-up resistors for detecting whether an external device is inserted, the present invention may set the pull-down resistor of the pre-detection circuit 20A to be greater than the pull-up resistor of the pre-detection circuit 20B for providing a condition V_{CC1}>ViH1 based on which the first electronic device M1 wakes up the connection circuit 10A, and set the specification-defined pull-down resistor of the first electronic device M1 to be smaller than the pull-up resistor of the pre-detection circuit 20B in the second electronic device M2 for providing a condition V_{CC1}′<ViL1′ based on which the second electronic device M2 wakes up the connection circuit 10B.

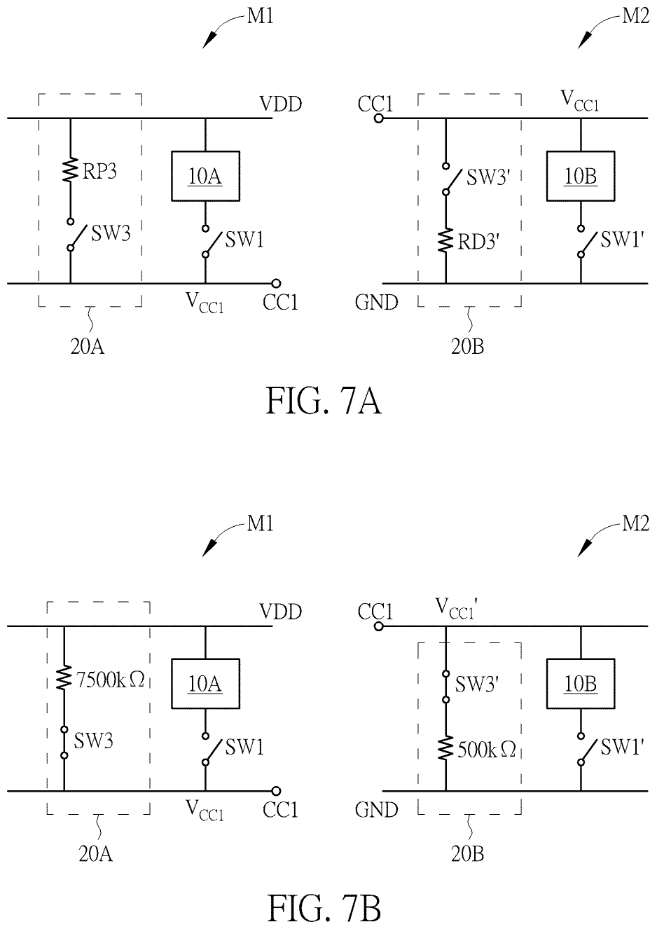

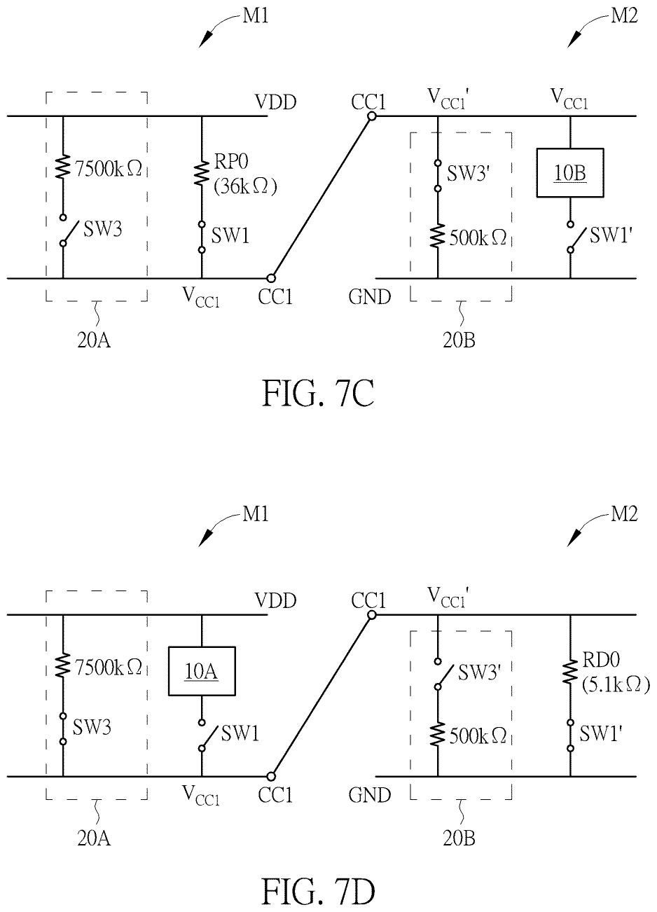

FIGS. 7A-7D are diagrams illustrating various circuit configurations of the connection detection circuit 100 depicted in FIG. 1A during operation according to embodiments of the present invention. For illustrative purpose, it is also assumed that the switching circuits SW3 and SW5 are set to the ON state by the control signals S3 and S5 outputted by the control circuit 24 and the switching circuits SW4 and SW6 are set to the OFF state by the control signals S4 and S6 outputted by the control circuit 24. That is, the second ends of the pull-up resistors RP3 and RP4 are respectively coupled to the configuration channel pins CC1 and CC2, and the first ends of the pull-down resistors RD3 and RD4 are respectively isolated from the configuration channel pins CC1 and CC2. Under such circumstance, the configuration channel pins CC1 and CC2 of the first electronic device M1 are coupled to the bias voltage VDD respectively via the pull-up resistors RP3 and RP4, and the pre-detection circuit 20A of the first electronic device M1 is configured to detect whether an external device (such as the second electronic device M2) is inserted into the first electronic device M1 using the pull-up resistors RP3 and RP4. Meanwhile, it is also assumed that the second electronic device M2 is configured to detect whether an external device (such as the first electronic device M1) is inserted using the pull-up resistors RP3′ and RP4′ in the same manner. For ease of explanation, FIGS. 7A-7D only depict the operation of connection detection association with the configuration channel pin CC1. Detailed descriptions of connection detection associated with the configuration channel pin CC2 are omitted for clarity.

In the embodiment depicted in FIG. 7A, the pull-up resistor RP3 in the pre-detection circuit 20A of the first electronic device M1 is greater than the pull-down resistor RD3′ in the pre-detection circuit 20B of the second electronic device M2. For example, the value of the pull-up resistor RP3 may be 7500 kΩ, and the value of the pull-down resistor RD3′ may be 500 kΩ.

As depicted in FIG. 7B, when the first electronic device M1 and the second electronic device M2 are not connected to each other, the first electronic device M1 and the second electronic device M2 are configured to detect whether an external device is inserted using the pre-detection circuits 20A and 20B, respectively, while the connection circuits 10A and 10B are turned off for reducing power consumption. Under such circumstances, the voltage V_{CC1} associated with the configuration channel pin CC1 of the first electronic device M1 is pulled up to the bias voltage VDD via the pull-up resistor RP3 (e.g., 7500 kΩ), and the voltage V_{CC1}′ associated with the configuration channel pin CC1 of the second electronic device M2 is pulled down to the ground level GND via the pull-down resistor RD3′ (e.g., 500 kΩ). In other words, when the first electronic device M1 and the second electronic device M2 are not connected to each other, the configuration channel pin CC1 of the first electronic device M1 is at a high logic level, and the configuration channel pin CC1 of the second electronic device M2 is at a low logic level.

As depicted in FIG. 7C, after the first electronic device M1 and the second electronic device M2 are connected to each other, the configuration channel pin CC1 of the first electronic device M1 and the configuration channel pin CC1 of the second electronic device M2 are at the same level (V_{CC1}=V_{CC1}′). Since the pull-up ability of the pull-up resistor RP3 (e.g., 7500 kΩ) is weaker than the pull-down ability of the pull-down resistor RD3′ (e.g., 500 kΩ), the voltage V_{CC1} associated with the configuration channel pin CC1 of the first electronic device M1 is thus pulled down from the bias voltage VDD. When the voltage V_{CC1} is smaller than the input low voltage ViL1 of the comparator CP1, the first electronic device M1 determines that the voltage V_{CC1} has switched from a high logic level to a low logic level, thereby determining that an external device (such as the second electronic device M2) is inserted into the first electronic device M1. Under such circumstance, the first electronic device M1 is configured to turn off the pre-detection circuit 20A (by setting the switching circuit SW3 to the OFF state) and turn on the connection circuit 10A (by setting the switching circuit SW1 to the ON state) for providing connection status detection function with high accuracy. In this case, the equivalent resistor of the connection circuit 10A in the first electronic device M1 is equal to a specification-defined pull-up resistor RP0 (e.g., 36 kΩ).

As depicted in FIG. 7D, after the first electronic device M1 turns off the pre-detection circuit 20A and turns on the connection circuit 10A, since the specification-defined pull-up resistor RP0 (e.g., 36 kΩ) of the first electronic device M1 is smaller than the pull-down resistor RD3′ (e.g., 500 kΩ) in the pre-detection circuit 20B of the second electronic device M2, the pull-up ability of the specification-defined pull-up resistor RP0 (e.g., 36 kΩ) thus becomes stronger than the pull-down ability of the pull-down resistor RD3′ (e.g., 500 kΩ), thereby pulling up the voltage V_{CC1}′ associated with the configuration channel pin CC1 of the second electronic device M2 from the ground level GND. When the voltage V_{CC1}′ is greater than the input high voltage ViH1′ of the comparator CP1′, the second electronic device M2 determines that the voltage V_{CC1}′ has switched from a low logic level to a high logic level, thereby determining that an external device (such as the first electronic device M1) is inserted into the second electronic device M2. Under such circumstance, the second electronic device M2 is configured to turn off the pre-detection circuit 20B (by setting the switching circuit SW3′ to the OFF state) and turn on the connection circuit 10B (by setting the switching circuit SW1′ to the ON state) for providing connection status detection function with high accuracy. In this case, the equivalent resistor of the connection circuit 10B in the second electronic device M2 is equal to a specification-defined pull-down resistor RD0 (e.g., 5.1 kΩ).

As depicted in FIGS. 7A-7D, in the case when the first electronic device M1 uses pull-up resistors and the second electronic device M2 uses pull-down resistors for detecting whether an external device is inserted, the present invention may set the pull-up resistor of the pre-detection circuit 20A to be greater than the pull-down resistor of the pre-detection circuit 20B for providing a condition V_{CC1}<ViL1 based on which the first electronic device M1 wakes up connection 10A, the circuit and set the specification-defined pull-up resistor of the first electronic device M1 to be smaller than the pull-down resistor of the pre-detection circuit 20B for providing a condition V_{CC1}′>ViH1′ based on which the second electronic device M2 wakes up the connection circuit 10B.

Similarly, in the case when the first electronic device M1 uses pull-down resistors and the second electronic device M2 uses pull-up resistors for detecting whether an external device is inserted, the present invention may set the pull-down resistor of the pre-detection circuit 20A to be smaller than the pull-up resistor of the pre-detection circuit 20B for providing a condition V_{CC1}<ViL1′ based on which the second electronic device M2 wakes up the connection circuit 10B, and set the pull-down resistor of the pre-detection circuit 20A in the first electronic device M1 to be greater than the specification-defined pull-up resistor of the second electronic device M2 for providing a condition V_{CC1}>ViH1 based on which the first electronic device M1 wakes up the connection circuit 10A.

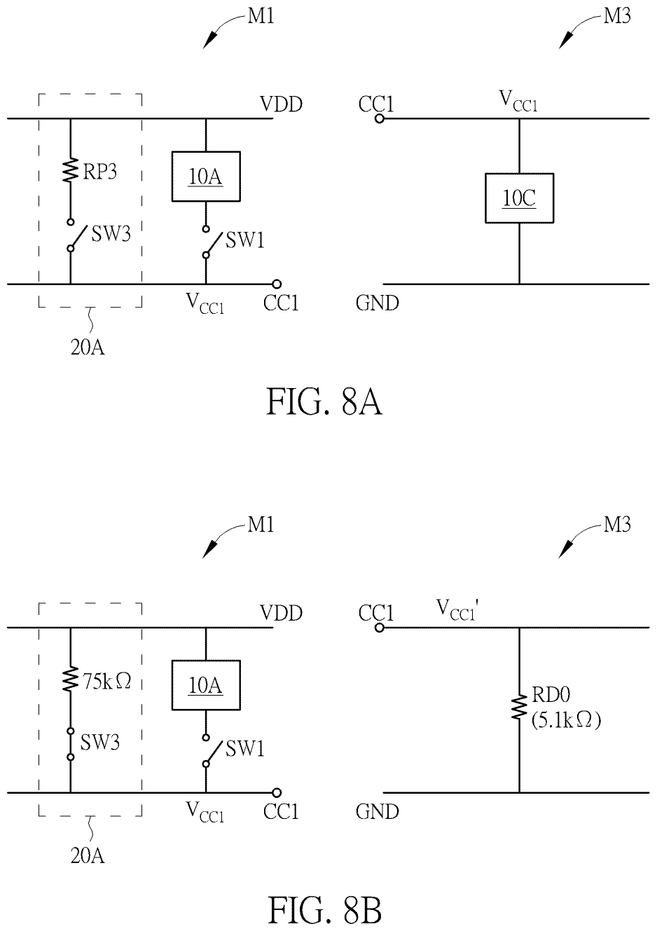

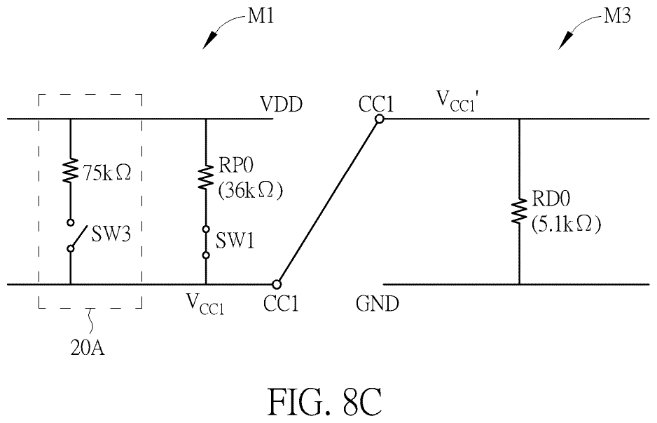

FIGS. 8A-8C are diagrams illustrating various circuit configurations of the connection detection circuit 100 depicted in FIG. 1B during operation according to embodiments of the present invention. For illustrative purpose, it is also assumed that the switching circuits SW3 and SW5 are set to the ON state by the control signals S3 and S5 outputted by the control circuit 24 and the switching circuits SW4 and SW6 are set to the OFF state by the control signals S4 and S6 outputted by the control circuit 24. That is, the second ends of the pull-up resistors RP3 and RP4 are respectively coupled to the configuration channel pins CC1 and CC2, the first ends of the pull-down resistors RD3 and RD4 are respectively isolated from the configuration channel pins CC1 and CC2. Under such circumstance, the configuration channel pins CC1 and CC2 of the first electronic device M1 are coupled to the bias voltage VDD respectively via the pull-up resistors RP3 and RP4, and the pre-detection circuit 20A of the first electronic device M1 is configured to detect whether an external device (such as the third electronic device M3) is inserted into the first electronic device M1 using the pull-up resistors RP3 and RP4. Meanwhile, the third electronic device M3 is configured to detect whether an external device (such as the first electronic device M1) is inserted using the connection circuit 10C. For ease of explanation, FIGS. 8A-C only depict the operation of connection detection associated with the configuration channel pin CC1. Detailed descriptions of connection detection associated with the configuration channel pin CC2 are omitted for clarity.

In the embodiment depicted in FIG. 8A, the pull-up resistor RP3 in the pre-detection circuit 20A of the first electronic device M1 is greater than the specification-defined pull-down resistor RD0 of the connection circuit 10C in the third electronic device M3. For example, the value of the pull-up resistor RP3 may be 7500 kΩ, and the value of specification-defined pull-down resistor RD0 may be 5.1 kΩ.

As depicted in FIG. 8B, when the first electronic device M1 and the third electronic device M3 are not connected to each other, the first electronic device M1 and the third electronic device M3 are configured to detect whether an external device is inserted using the pre-detection circuit 20A and the connection circuit 10C, respectively, while the connection circuit 10A is turned off for reducing power consumption. Under such circumstance, the voltage V_{CC1} associated with the configuration channel pin CC1 of the first electronic device M1 is pulled up to the bias voltage VDD via the pull-up resistor RP3 (e.g., 75 kΩ), and the voltage V_{CC1}′ associated with the configuration channel pin CC1 of the third electronic device M3 is pulled down to the ground level GND via the connection circuit 10C. In other words, when the first electronic device M1 and the third electronic device M3 are not connected to each other, the configuration channel pin CC1 of the first electronic device M1 is at a high logic level, and the configuration channel pin CC1 of the second electronic device M2 is at a low logic level.

As depicted in FIG. 8C, after the first electronic device M1 and the third electronic device M3 are connected to each other, the configuration channel pin CC1 of the first electronic device M1 and the configuration channel pin CC1 of the second electronic device M2 are at the same level (V_{CC1}=V_{CC1}′). Since the pull-up ability of the pull-up resistor RP3 (e.g., 75 kΩ) is weaker than the pull-down ability of the specification-defined pull-down resistor RD0 (e.g., 5.1 kΩ), the voltage V_{CC1} associated with the configuration channel pin CC1 of the first electronic device M1 is thus pulled down from the bias voltage VDD. When the voltage V_{CC1} is smaller than the input low voltage Vill of the comparator CP1, the first electronic device M1 determines that the voltage V_{CC1} has switched from a high logic level to a low logic level, thereby determining that an external device (such as the third electronic device M3) is inserted into the first electronic device M1. Under such circumstance, the first electronic device M1 is configured to turn off the pre-detection circuit 20A (by setting the switching circuit SW3 to the OFF state) and turn on the connection circuit 10A (by setting the switching circuit SW1 to the ON state) for providing connection status detection function with high accuracy. In this case, the equivalent resistor of the connection circuit 10A in the first electronic device M1 is equal to a specification-defined pull-up resistor RP0 (e.g., 36 kΩ).

As depicted in FIGS. 8A-8C, in the case when the first electronic device M1 uses pull-up resistors for detecting whether an external device is inserted, the present invention may set the pull-up resistor of the pre-detection circuit 20A to be greater than the specification-defined pull-down resistor of the second electronic device M2 for providing a condition V_{CC1}<ViL1 based on which the first electronic device M1 wakes up the connection circuit 10A.

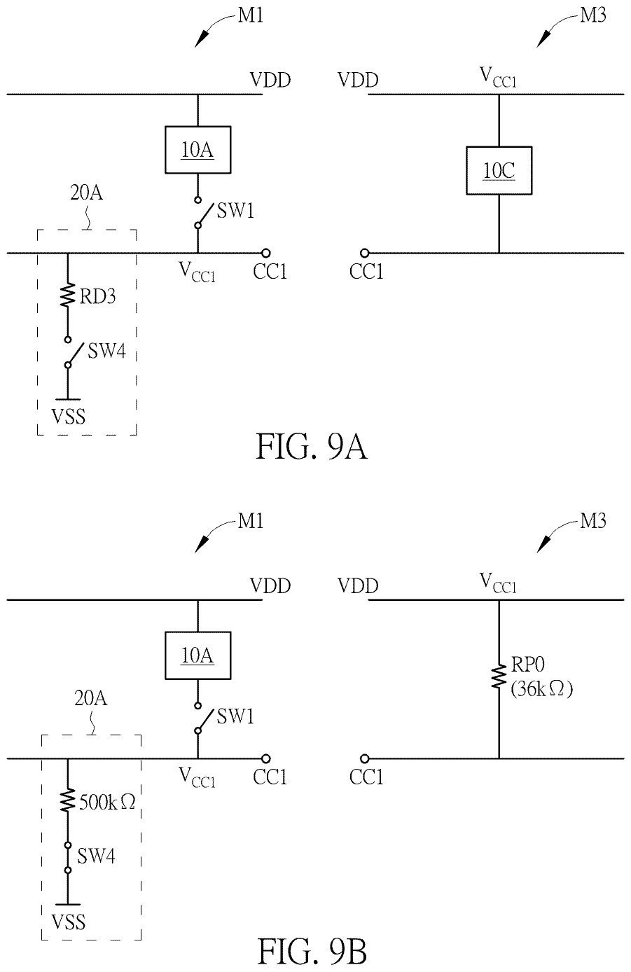

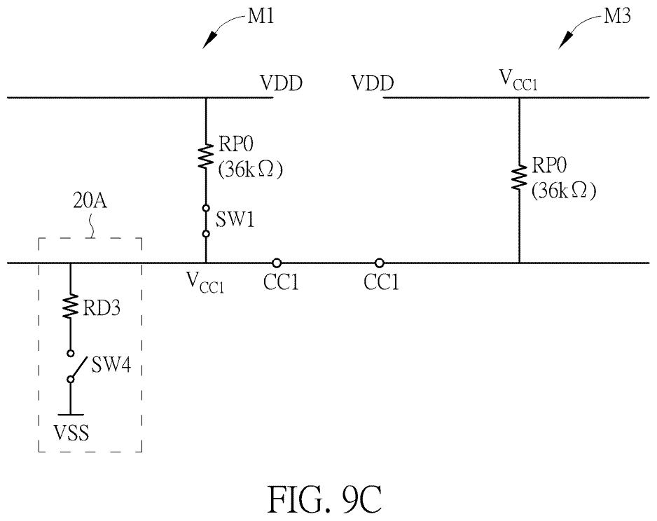

FIGS. 9A-9C are diagrams illustrating various circuit configurations of the connection detection circuit 100 depicted in FIG. 1B during operation according to embodiments of the present invention. For illustrative purpose, it is also assumed that the switching circuits SW3 and SW5 are set to the OFF state by the control signals S3 and S5 outputted by the control circuit 24 and the switching circuits SW4 and SW6 are set to the ON state by the control signals S4 and S6 outputted by the control circuit 24. That is, the first ends of the pull-up resistors RP3 and RP4 are respectively coupled to the configuration channel pins CC1 and CC2, the second ends of the pull-down resistors RD3 and RD4 are respectively isolated from the configuration channel pins CC1 and CC2. Under such circumstance, the configuration channel pins CC1 and CC2 of the first electronic device M1 are coupled to the bias voltage VSS respectively via the pull-down resistors RD3 and RD4, and the pre-detection circuit 20A of the first electronic device M1 is configured to detect whether an external device (such as the third electronic device M3) is inserted into the first electronic device M1 using the pull-down resistors RD3 and RD4. Meanwhile, the third electronic device M3 is configured to detect whether an external device (such as the first electronic device M1) is inserted using the connection circuit 10C. For ease of explanation, FIGS. 9A-9C only depict the operation of connection detection associated with the configuration channel pin CC1. Detailed descriptions of connection detection associated with the configuration channel pin CC2 are omitted for clarity.

In the embodiment depicted in FIG. 9A, the pull-down resistor RD3 in the pre-detection circuit 20A of the first electronic device M1 is greater than the specification-defined pull-up resistor RP0 of the connection circuit 10C in the third electronic device M3. For example, the value of the pull-up resistor RP3 may be 500 kΩ, and the value of specification-defined pull-up resistor RD0 may be 36 kΩ.

As depicted in FIG. 9B, when the first electronic device M1 and the third electronic device M3 are not connected to each other, the first electronic device M1 and the third electronic device M3 are configured to detect whether an external device is inserted using the pre-detection circuit 20A and the connection circuit 10C, respectively, while the connection circuit 10A is turned off for reducing power consumption. Under such circumstance, the voltage V_{CC1} associated with the configuration channel pin CC1 of the first electronic device M1 is pulled down to the negative bias voltage VSS via the pull-down resistor RD3 (e.g., 500 kΩ), and the voltage V_{CC1}′ associated with the configuration channel pin CC1 of the third electronic device M3 is pulled up to the positive bias voltage VDD via the connection circuit 10C. In other words, when the first electronic device M1 and the third electronic device M3 are not connected to each other, the configuration channel pin CC1 of the first electronic device M1 is at a low logic level, and the configuration channel pin CC1 of the second electronic device M2 is at a low logic level.

As depicted in FIG. 9C, after the first electronic device M1 and the third electronic device M3 are connected to each other, the configuration channel pin CC1 of the first electronic device M1 and the configuration channel pin CC1 of the third electronic device M3 are at the same level (V_{CC1}=V_{CC1}′). Since the pull-down ability of the pull-down resistor RD3 (e.g., 500 kΩ) is weaker than the pull-up ability of the specification-defined pull-up resistor RP0 (e.g., 36 kΩ), the voltage V_{CC1} associated with the configuration channel pin CC1 of the first electronic device M1 is thus pulled up from the negative bias voltage VSS. When the voltage V_{CC1} is greater than the input high voltage ViH1 of the comparator CP1, the first electronic device M1 determines that the voltage V_{CC1} has switched from a low logic level to a high logic level, thereby determining that an external device (such as the third electronic device M3) is inserted into the first electronic device M1. Under such circumstance, the first electronic device M1 is configured to turn off the pre-detection circuit 20A (by setting the switching circuit SW3 to the OFF state) and turn on the connection circuit 10A (by setting the switching circuit SW1 to the ON state) for providing connection status detection function with high accuracy. In this case, the equivalent resistor of the connection circuit 10A in the first electronic device M1 is equal to a specification-defined pull-up resistor RP0 (e.g., 36 kΩ).

As depicted in FIGS. 9A-9C, in the case when the first electronic device M1 uses pull-down resistors for detecting whether an external device is inserted, the present invention may set the pull-down resistor of the pre-detection circuit 20A to be greater than the specification-defined pull-up resistor of the second electronic device M2 for providing a condition V_{CC1}>ViH1 based on which the first electronic device M1 wakes up the connection circuit 10A.

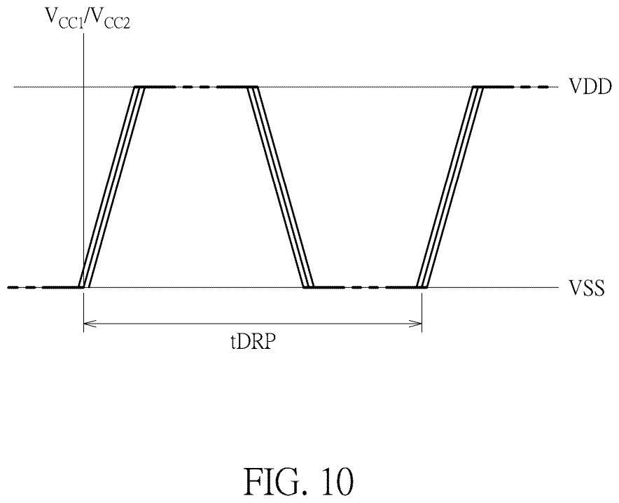

In an embodiment, the control signals S3-S6 outputted by the control circuit 24 may control the switching circuits SW3-SW6 to operate in a mode similar to a dual role of power (DRP) mode defined in USB PD protocols. FIG. 10 is a signal diagram illustrating the operation of the pre-detection circuit 20A in the DRP mode according to an embodiment of the present invention. In this embodiment, the pre-detection circuit 20A periodically switches between using the pull-up resistors RP3/RP4 and using the pull-down resistors RD3/RD4 for detecting connection. For example, the pre-detection circuit 20A is configured to use the pull-up resistors RP3/RP4 for detecting connection during the first half of each period tDRP and use the pull-down resistors RD3/RD4 for detecting connection during the second half of each period tDRP, as depicted in FIG. 10.

The embodiment of FIG. 3 is used for illustrating the operation of the connection circuit 10A. As previously stated, in the embodiment when the first electronic device M1 functions as a PD source device, the connection circuit 10A is configured to use the pull-up resistors RP1 and RP2 for detecting the connection status. In the embodiment when the first electronic device M1 functions as a PD sink device, the connection circuit 10A is configured to use the pull-down resistors RD1 and RD2 for connection detection. In another embodiment, the first electronic device M1 is configured to periodically switch between functioning as a PD source device and a PD sink device in the DRP mode, wherein the connection circuit 10A is configured to periodically switch between using the pull-up resistors RP1/RP2 and the pull-down resistors RD1/RD2 for connection detection, as depicted in FIG. 10.

The following Table 1 depicts the CC1/CC2 states of PD source device defined in related USB specification. Detailed descriptions of each connection status well-known to those skilled in the art are omitted for clarity. As previously stated, the comparator 121 may determine the load impedance of the configuration channel pins CC1/CC2, and the data depicted in the following Table 1 may be stored in the state machine 122. Therefore, it can be determined whether the second electronic device M2 or the third electronic device M3 is inserted into the first electronic device M1 based on the result of the comparator 121.

TABLE 1

| | CC1 | CC2 | Connection Status |
|---|---|---|---|
| State 1 | open | open | Nothing attached |
| State 2 | Rd | open | Sink attached |
| State 3 | open | Rd | |
| State 4 | open | Ra | Power Cable without sink attached |
| State 5 | Ra | open | |
| State 6 | Rd | Ra | Power Cable with sink attached |
| State 7 | Ra | Rd | |
| State 8 | Rd | Rd | Debug accessory mode attached |
| State 9 | Ra | Ra | Audio adaptor accessory mode |
| | | | attached |

In an embodiment of the present invention, the pre-detection circuit 20A may be implemented in a General Purpose Input/Output (GPIO) pad of the first electronic device M1, but is not limited thereto.

In conclusion, the present connection detection circuit 100 may be implemented in the first electronic device M1. When the first electronic device M1 operates in the power-saving mode, the connection detection circuit 100 turns off the connection circuit 10A with higher power consumption, and turns on the pre-detection circuit 20A with lower power consumption for determining whether the second electronic device M2 or the third electronic device M3 is inserted into the first electronic device M1. When the first electronic device operates in the normal mode or when the pre-detection circuit 20A determines that the second electronic device M2 or the third electronic device M3 is inserted into the first electronic device M1 during the power-saving mode, the connection detection circuit 100 turns off the pre-detection circuit 20A with lower detection accuracy, and turns on the connection circuit 10A with higher detection accuracy for accurately determining the connection status of the first electronic device M1 and the second electronic device M2/the third electronic device M3. Therefore, the present invention is able to maintain low-power connection detection function in the power-saving mode and wake up the complete connection status detection function in response to detecting the insertion of an external device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A connection detection circuit implemented in a first electronic device for maintaining low-power connection detection function in a power-saving mode, comprising:
a first pre-detection circuit configured to turn on after the first electronic device switches from a normal mode to the power-saving mode for determining whether a second electronic device is inserted into the first electronic device; and
a first connection circuit configured to:
turn on when the first electronic device operates in the normal mode;
turn off after the first electronic device switches from the normal mode to the power-saving mode; and
turn on after the first pre-detection circuit determines that the second electronic device is inserted into the first electronic device when the first electronic device operates in the power-saving mode for determining a connection status of the first electronic device and the second electronic device, wherein:
the first electronic device consumes more power when operating in the normal mode than when operating in the power-saving mode;
the first connection circuit in operation consumes more power than the first pre-detection circuit in operation; and
accuracy of the first connection circuit in detecting connection status is better than accuracy of the first pre-detection circuit in detecting connection status.

2. The connection detection circuit of claim 1, wherein:
the second electronic device comprises:
a second pre-detection circuit configured to:
turn on after the second electronic device switches from the normal mode to the power-saving mode for determining whether the first electronic device is inserted into the second electronic device; and
turn off after determining in the power-saving mode that the first electronic device is inserted into the second electronic device at a first time point; and
a second connection circuit configured to:
turn off after the second electronic device switches from the normal mode to the power-saving mode; and
turn on at the first time point;
after the first pre-detection circuit determines in the power-saving mode that the second electronic device is inserted into the first t electronic device, the first electronic device is configured to turn off the first pre-detection circuit and turn on the first connection circuit at a second time point for determining the connection status of the first electronic device and the second electronic device; and
the second time point occurs after the first time point.

3. The connection detection circuit of claim 2, wherein:
the first pre-detection circuit comprises:
a first switching circuit;
a second switching circuit;
a first pull-up resistor including:
a first end coupled to a first bias voltage; and
a second end selectively coupled to a first configuration channel (CC) pin of the first electronic device via the first switching circuit;
a first pull-down resistor including:
a first end selectively coupled to the first CC pin of the first electronic device via the second switching circuit; and
a second end coupled to a second bias voltage;
a first comparator including:
an input end coupled to the first CC pin of the first electronic device; and
an output end for outputting a first voltage; and
a first control circuit configured to:
determine whether the second electronic device is inserted into the first electronic device based on the first voltage; and
provide a first control signal for controlling a state of the first switching circuit and provide a second control signal for controlling a state of the second switching circuit, thereby coupling the first CC pin of the first electronic device to the first bias voltage or the second bias voltage; and
the second pre-detection circuit comprises:
a third switching circuit;
a fourth switching circuit;
a second pull-up resistor including:
a first end coupled to the first bias voltage; and
a second end selectively coupled to a second CC pin of the second electronic device via the third switching circuit;
a second pull-down resistor including:
a first end selectively coupled to the second CC pin of the second electronic device via the fourth switching circuit; and
a second end coupled to the second bias voltage;
a second comparator including:
an input end coupled to the second CC pin of the second electronic device; and
an output end for outputting a second voltage; and
a second control circuit configured to:
determine whether the first electronic device is inserted into the second electronic device based on the second voltage; and
provide a third control signal for controlling a state of the third switching circuit and provide a fourth control signal for controlling a state of the fourth switching circuit, thereby coupling the second CC pin of the second electronic device to the first bias voltage or the second bias voltage.

4. The connection detection circuit of claim 3, wherein:
the first pull-up resistor of the first pre-detection circuit is smaller than the second pull-down resistor of the second pre-detection circuit;
the first pull-up resistor of the first pre-detection circuit is greater than a specification-defined pull-down resistor of the second connection circuit;
when a voltage level of the second CC pin is higher than an input high voltage of the second comparator at the first time point, the second electronic device is configured to turn off the second pre-detection circuit and turn on the second connection circuit; and
when a voltage level of the first CC pin is lower than an input low voltage of the first comparator at the second time point, the first electronic device is configured to turn off the first pre-detection circuit and turn on the first connection circuit.

5. The connection detection circuit of claim 1, wherein:
after the first pre-detection circuit determines in the power-saving mode that the second electronic device is inserted into the first electronic device, the first electronic device is configured to turn off the first pre-detection circuit and turn on the first connection circuit at a first time point for determining the connection status of the first electronic device and the second electronic device;
the second electronic device comprises:
a second pre-detection circuit configured to:
turn on after the second electronic device switches from the normal mode to the power-saving mode for determining whether the first electronic device is inserted into the second electronic device; and
turn off after determining in the power-saving mode that the first electronic device is inserted into the second electronic device at a second time point; and
a second connection circuit configured to:
turn off after the second electronic device switches from the normal mode to the power-saving mode; and
turn on at the second time point; and
the second time point occurs after the first time point.

6. The connection detection circuit of claim 5, wherein:
the first pre-detection circuit comprises:
a first switching circuit;
a second switching circuit;
a first pull-up resistor including:
a first end coupled to a first bias voltage; and
a second end selectively coupled to a first CC pin of the first electronic device via the first switching circuit;
a first pull-down resistor including:
a first end selectively coupled to the first CC pin of the first electronic device via the second switching circuit; and
a second end coupled to a second bias voltage;
a first comparator including:
an input end coupled to the first CC pin of the first electronic device; and
an output end for outputting a first voltage; and
a first control circuit configured to:
determine whether the second electronic device is inserted into the first electronic device based on the first voltage; and
provide a first control signal for controlling a state of the first switching circuit and provide a second control signal for controlling a state of the second switching circuit, thereby coupling the first CC pin of the first electronic device to the first bias voltage or the second bias voltage; and
the second pre-detection circuit comprises:
a third switching circuit;
a fourth switching circuit;
a second pull-up resistor including:
a first end coupled to the first bias voltage; and
a second end selectively coupled to a second CC pin of the second electronic device via the third switching circuit;
a second pull-down resistor including:
a first end selectively coupled to the second CC pin of the second electronic device via the fourth switching circuit; and
a second end coupled to the second bias voltage;
a second comparator including:
an input end coupled to the second CC pin of the second electronic device; and
an output end for outputting a second voltage; and
a second control circuit configured to:
determine whether the first electronic device is inserted into the second electronic device based on the second voltage; and
provide a third control signal for controlling a state of the third switching circuit and provide a fourth control signal for controlling a state of the fourth switching circuit, thereby coupling the second CC pin of the second electronic device to the first bias voltage or the second bias voltage.

7. The connection detection circuit of claim 6, wherein:
the first pull-up resistor of the first pre-detection circuit is greater than the second pull-down resistor of the second pre-detection circuit;
a specification-defined pull-up resistor of the second connection circuit is smaller than the second pull-down resistor of the second pre-detection circuit;
when a voltage level of the first CC pin is lower than an input low voltage of the first comparator at the first time point, the first electronic device is configured to turn off the first pre-detection circuit and turn on the first connection circuit; and
when a voltage level of the second CC pin is higher than an input high voltage of the second comparator at the second time point, the second electronic device is configured to turn off the second pre-detection circuit and turn on the second connection circuit.

8. The connection detection circuit of claim 1, wherein:
the first pre-detection circuit comprises:
a first switching circuit;
a second switching circuit;
a first pull-up resistor including:
a first end coupled to a first bias voltage; and
a second end selectively coupled to a first CC pin of the first electronic device via the first switching circuit;
a first pull-down resistor including:
a first end selectively coupled to the first CC pin of the first electronic device via the second switching circuit; and
a second end coupled to a second bias voltage;
a first comparator including:
an input end coupled to the first CC pin of the first electronic device; and
an output end for outputting a first voltage; and
a first control circuit configured to:
determine whether the second electronic device is inserted into the first electronic device based on the first voltage; and
provide a first control signal for controlling a state of the first switching circuit and provide a second control signal for controlling a state of the second switching circuit, thereby coupling the first CC pin to the first bias voltage or the second bias voltage; and
the second electronic device comprises a second connection circuit configured to determine whether an external device is inserted into the second electronic device.

9. The connection detection circuit of claim 8, wherein:
the first pull-up resistor of the first pre-detection circuit is greater than a specification-defined pull-down resistor of the second connection circuit;
when a voltage level of the first CC pin is lower than an input low voltage of the first comparator, the first electronic device is configured to turn off the first pre-detection circuit and turn on the first connection circuit.

10. The connection detection circuit of claim 8, wherein:
the first pull-down resistor of the first pre-detection circuit is greater than a specification-defined pull-up resistor of the second connection circuit; and
when a voltage level of the first CC pin is greater than an input high voltage of the first comparator, the first electronic device is configured to turn off the first pre-detection circuit and turn on the first connection circuit.
